(19) United States
(12) Patent Application Publication
(10) Pub. No.: US 2026/0211471 A1
(43) Pub. Date: Jul. 23, 2026

(54) DEVICE, SYSTEM AND METHOD FOR COOLING A PROCESSOR

(71) Applicant: TECHN GmbH, Berlin (DE)

(72) Inventor: Nikolaus KOHL, Berlin (DE)

(21) Appl. No.: 19/141,403

(22) PCT Filed: Dec. 19, 2023
(86) PCT No.: PCT/EP2023/086568

§ 371 Date: Jun. 20, 2025

(30) Foreign Application Priority Data
Dec. 23, 2022 (EP) 22216338.8

(51) Int. Cl. G06F 1/20; H05K 7/20

(52) U.S. Cl. CPC G06F 1/20; H05K 7/20163; H05K 7/20263; H05K 7/20272; H05K 7/20409; G06F 2200/201

(57) ABSTRACT

A cooler for a processor, in particular for a CPU or a GPU, as well as to a system for cooling a processor and a method for cooling a processor.

The present invention relates to a cooler for a processor, in particular for a CPU or a GPU, as well as to a system for cooling a processor and a method to cool a processor.

When electronic components are in operation, in particular processors, heat is produced that can lead to unwanted temperature rises within the component. To counteract such a rise in temperature, suitable cooling systems can be used to dissipate the heat generated by the electrical components. Fluid-cooled cooling systems, as known from the prior art, enable a disspitation of the processor's waste heat by means of a fluid. The processor is brought into thermal contact with a cooler in the liquid-cooled cooling system so that it can absorb the waste heat from the processor. The cooler itself is cooled by a coolant (such as water), which is conveyed through a cooling duct in the heat sink.

Heat can be efficiently dissipated by minimising any thermal resistance occurring between the processor and the coolant. Typically, heat dissipation can typically be achieved by the coolant coming into contact with the heat sink at any point of the cooling duct.

Fluid-cooled cooling systems, such as liquid-cooled cooling systems, can be designed as a closed system. Such cooling systems may comprise a pump to pump coolant liquid through a cooling circuit and a radiator which uses the coolant liquid to dissipate heat energy. When liquid-cooled cooling systems are in operation, it is common for air and/or gas to be entrained by the coolant and/or separated, i.e. discharged, from the liquid during the cooling system's operation and/or service life. When providing such a liquid-cooled cooling system, it is also difficult to avoid air and/or a gas becoming trapped in the cooling liquid circuit's cooling duct. Regardless of this, gas and/or air can also enter the cooling circuit through leaks in the cooling system and/or via diffusion. Whenever gas or separated gas is mentioned below, this refers to gas and/or air that is in the cooling circuit, regardless of how it entered the cooling circuit and what type of gas it is.

Typically, the separated gas has a lower thermal conductivity coefficient than the coolant and can therefore help to increase the thermal resistance between the processor and the coolant. Regardless of this, the gas can cause unwanted noise, reduce the pump's flow rate, or cause it to fail, for example if large amounts of gas accumulate in the pump. Gas accumulating in certain areas of the cooling circuit should be avoided for the cooling system to operate optimally.

The gas is typically lighter than the coolant and is separated against the direction of gravity, i.e. upwards. In fluid-cooled systems, it is therefore often the case that the system components are arranged only at certain heights in relation to each other and/or in certain orientations to the force of gravity. This is to prevent the gas from accumulating in areas that could adversely affect such a cooling system's operation.

In particular, when operated in a certain installation position, i.e. when oriented in a certain direction in relation to the direction of gravity, fluid-cooled cooling systems of the prior art enable a processor to be cooled efficiently.

Specifically, this means that the processor, in particular a CPU or a GPU, can usually only be operated when installed in a single specific position, which is generally vertical or horizontal.

The object of the present invention is to provide a cooler, a cooling system, and a method to operate a cooler, which at least partly solve the problems mentioned above.

The object is solved by a cooler, the cooling system, and the method according to the independent claims. The invention's advantageous further developments are specified by the dependent claims.

The invention is based on the idea of providing volumes within the cooler that are suitable for absorbing and storing the separated gases in at least two installation positions of the cooler and are arranged such as to not impair the thermal resistance between the processor and the cooling liquid. In particular, the accumulation of the gas separated from the coolant in an area within the cooler positioned directly between the processor and the coolant should be avoided.

A cooler for a processor, according to the invention, in particular for a CPU or a GPU, has a heat sink with an outer cooling surface to cool the processor. The exterior cooling surface is a partial surface of the heat sink's outer surface that is designed to absorb heat, in particular the waste heat from a processor. Optionally, the cooler can have at least one further cooling surface, which is designed to cool at least one further electronic component, one further processor, in particular a CPU or GPU, and/or at least one heat-emitting or heat-producing area of a printed circuit board. An electronic component can be understood to mean any electronic element that produces waste heat during operation; in particular, it can be understood to mean electronic circuits, integrated circuits (ICs) or other programmable or non-programmable arithmetic units.

In some cases, the heat sink's shape may be adapted to the processor requiring cooling. In some embodiments, the heat sink can have materials with a high thermal conductivity, in particular at least part aluminum or copper. Regardless of this, the heat sink or parts of the heat sink can be manufactured using an injection moulding, die casting or 3D printing process, for example. In one embodiment of the heat sink, it can have restraints to hold the heat sink, for example, inside a housing, in particular inside a computer chassis. In an optional heat sink design, the heat sink can be affixed to sensors whose signals can be used to control and/or to provide control assistance to a cooling circuit.

As an advantage, the exterior cooling surface can be designed to adapt to the processor's geometry, particularly to a partial surface of the processor designed to dissipate the waste heat generated by the processor. Independently of this, the surface of the exterior cooling surface can be partially or completely functionalised by coatings or surface treatment processes such to increase its heat transfer coefficiency. To compensate for tolerances, a thermally-conductive paste may be applied between the processor and the external cooling surface.

Furthermore, the cooler has a duct that runs through the heat sink and is designed to convey a coolant. Coolant can therefore flow into the duct via an inlet and out of the duct via an outlet. A heat transfer between the heat sink and the coolant can potentially occur at every interface between the duct and the heat sink, which will be referred to in the following as the duct wall. The duct's path through the heat sink, i.e. the path along which the duct extends, can be adapted to the heat sink's geometry. For example, the duct can be designed such that the heat sink's wall thickness is in sections constant. To be able to create the largest possible surface area for a transfer of heat between the heat sink and the coolant, the duct's path can, for example, at least partially meander. As an advantage, both the shape and the surface area of a duct's cross-section can vary along the duct's path and do not have to be constant. Cross-sectionally, the duct can in some sections be round and/or polygonal in shape, such as rectangular, whereby the corners can be rounded.

The duct's inlet and outlet may have fasteners for the fluid lines so that a coolant can be transported to the duct's inlet, for example, via a first fluid line and can be transported away from the duct's outlet via a second fluid line. In optional duct designs, the duct can be designed such that the cooler functions independently of the coolant's direction of flow. In these optional cases, the duct's inlet and outlet are interchangeable without consequence in the description above and below.

The duct also has an interior cooling surface. The interior cooling surface is a partial surface of the duct wall and is designed as a projection of the exterior cooling surface onto the nearest duct wall. The straight projection lines can be chosen to be the shortest connection between any point of the exterior cooling surface and the duct wall. The interior cooling surface can thus be the area of the duct wall with the lowest thermal resistance to the exterior cooling surface. There may be embodiments in which the section of the duct wall closest to the exterior cooling surface is parallel to the exterior cooling surface. In this case, the interior cooling surface is the orthogonal projection of the exterior cooling surface onto the duct wall.

In optional cases, the cooler can have several exterior cooling surfaces, in which case interior cooling surfaces can result as an orthogonal projection of the respective exterior cooling surface onto the duct wall. Irrespective of this, areas of the heat sink's outer surface that are not part of the exterior cooling surface may be suitable for cooling further electronic circuits and/or for additional cooling of the at least one processor. The heat sink can therefore be designed to particularly cool several electronic components that may be arranged on a circuit board, for example.

The heat sink also has at least one air reservoir connected to the duct. The air reservoir is usually at least one volume that is enclosed by the heat sink and connected to the duct. Furthermore, the air reservoir is arranged outside the projection lines of the interior cooling surface and the exterior cooling surface. For the following description, two installation positions, a first and a second installation position, are defined, each of which describes a specific orientation of the cooler in relation to the direction of gravity. Several installation positions can also be provided. Certain installation positions may be necessary, for example, because a processor, in particular a CPU or a GPU, is arranged on a circuit board. The circuit board can be plugged into a main board at an angle of essentially 90°. In this context, “essentially 90°” means that deviations of no more than 10°, preferably no more than 5°, and in particular no more than 2° from 90°, are possible. Typically, the main board is essentially aligned horizontally or vertically, for example in relation to a computer chassis, which may correspondingly cause the processor to be vertically or horizontally orientated. Where reference is made here and in the following to vertical or horizontal directions, this also includes directions which preferably deviate less than 15°, particularly preferably less than 10°, very particularly preferably less than 5°, in particular less than 2° from the vertical or horizontal direction.

The air reservoir is designed such that air and/or a gas can be separated into at least one subvolume of the air reservoir in each of the two installation positions. When it comes to the air reservoir being able to “be separated into a subvolume”, this means that a gas that separates from the coolant or is entrained by it can be directed into the air reservoir and can also remain there or be collected there. As the air reservoir is not located in the area of the interior cooling surface, a gas that is separated from the coolant into a subvolume of the air reservoir cannot accumulate as regards the interior cooling surface and does not displace any coolant flowing past there. The coolant can therefore be in full contact with the interior cooling surface, allowing heat to be efficiently dissipated via the coolant. In particular, more than 90%, advantageously more than 95%, or most advantageously more than 99%, of the interior cooling surface can be in contact with the cooling liquid.

The air reservoir can optionally be arranged in areas of the duct where, when the cooling liquid flows through it, boundary layer separation occurs, i.e. the liquid detaches from the duct wall. Such areas can also be referred to as dead spaces or vortex spaces. Dead spaces can occur, for example, in the duct along the coolant's direction of flow after sharp edges or any sudden enlargements in the duct's cross-section. In conjunction with the air reservoirs, the arising dead spaces can be used to absorb and store gas released from the coolant. The air reservoir can also be arranged at an angle to or against the direction of coolant's flow after a change in the duct's direction.

As an advantage, in each of the two installation positions, at least a subvolume of the air reservoir can be arranged higher in the direction of gravity than at least one area of the duct adjacent to the air reservoir. This means that a gas that has been sealed in there cannot escape from the respective subvolume in either of the two installation positions, which enables the gas to be stored permanently in this subvolume in any installed position. In an optional embodiment of the invention, areas of the duct that are not adjacent to the air reservoir can be arranged higher than the air reservoir's subvolume into which a gas can be separated, in at least one of the two installation positions. The subvolume described above does not necessarily have to be identical for each of the installation positions. For example, the subvolumes may differ, with air being separable into a first subvolume in a first installation position and air being separable into a second subvolume in a second installation position, the subvolumes may differ. The first and second subvolumes can at least partially overlap or disjoint, i.e. separate.

Optionally, in the region of the the interior cooling surface, the cross-section of the duct can be smaller than in an immediately preceding region of the duct in the coolant's direction of flow. As regards the interior cooling surface, the reduction of the duct's cross-section can cause an increase in the coolant's flow velocity in this area. Heat can then be efficiently removed because the likelihood of a separation of the boundary layer of the coolant as regards the internal cooling surface is reduced, ensuring that the coolant is in contact with the interior cooling surface. The separation of the gas dissolved in the coolant or the gas entrained by the coolant typically takes place at low flow rates.

In an optional cooler embodiment, the exterior cooling surface is designed in such a way that, in the cooler's first installation position, it extends essentially perpendicular in the direction of gravity and/or in the second installation position it extends essentially parallel to the direction of gravity. This may mean that the exterior cooling surface is essentially horizontal in the first installation position and essentially vertical in the second installation position. The exterior cooling surface can be adapted to the shape of the processor requiring cooling and does not necessarily have to be flat, for example.

In a further embodiment of the invention, the air reservoir can have two air reservoir segments, for example a first air reservoir segment and a second air reservoir segment, which are spatially separated from one another and are fluidically connected to one another only via the duct. The two air reservoir segments can be designed, for example, so that gas can be separated into a subvolume of the first air reservoir segment in the first installation position and gas can be separated into a subvolume of the second air reservoir segment in the second installation position. It is also conceivable that a gas is deposited in each of the two air reservoir segments in each of the two installation positions.

An embodiment of the cooler for a processor is also conceivable, in which the exterior cooling surface has a fastening option for a processor. The mounting option can, for example, have fasteners such as screws or brackets. As an advantage, the fasteners can be used to build up a contact pressure that enables a secure connection between the exterior cooling surface and a surface of the processor that is designed to dissipate the waste heat. However, other means of attachment such as adhesive or heat-conducting pads are also conceivable. To increase the heat transfer from the processor to the exterior cooling surface, measures such as heat transfer paste or heat transfer pads can also or additionally be used independently of any mounting option.

In a further optional embodiment of the invention, the cooler has two interconnected trays. A first tray has a first connecting surface and a second tray has a second connecting surface. The two trays are placed against the connecting surfaces, are connected to each other at the respective connecting surfaces and, in combination, form the heat sink, the duct and the air reservoir(s). The two trays can be shaped such that the duct wall is both part of the first tray and part of the second tray at each point of a certain section along the duct. Optionally, at least in sections, the duct can run perpendicular to the trays' connecting surfaces. Regardless of this, the duct can at least partially run parallel to the connecting surfaces and/or at least partially along the connecting surfaces.

Each of the two trays can also be assembled from several tray components. It is also conceivable that the heat sink itself is composed of several components, which will also be referred to below as tray components. Sealing elements can also be provided on the connecting surfaces, particularly on the trays' connecting surfaces, to ensure that the two trays are tightly connected. The trays and/or tray components can be connected to each other using various fasteners. Examples include screws, bolts or brackets. Likewise, connections made by joining, gluing and/or welding are also possible. The two trays and/or the tray components can be manufactured using a milling, injection moulding, die casting or 3D printing process, for example. At least one of the trays can be made of aluminium, for example.

In a further embodiment of the invention, the interior cooling surface comprises a micro-duct heat exchanger with grooves aligned along the direction of flow. This enables an increase of the surface area around the flow, which contributes to improved heat exchange on the interior cooling surface. Designs of the interior cooling surface that increase the heat transfer at the interior cooling surface, for example through surface functionalisation, are also conceivable. Regardless of this, it is conceivable to form the internal cooling surface convexly in the coolant's direction, or to form the duct's cross-section adjacent to the interior cooling surface so that it tapers continuously in the direction of flow.

In an optional embodiment of the invention, the air reservoir can be designed such that, in each of the two installation positions, at least one corresponding subvolume within the air reservoir is arranged higher than any point of the interior cooling surface along the force of gravity. For example, it may be the case that in a first installation position a first subvolume, in a second installation position a second subvolume and in a third installation position a third subvolume within the air reservoir are arranged higher along the force of gravity than any point of the interior cooling surface. The number of installation positions is not limited to three. The subvolume described can be different subvolume, which can be disjoint, for example. In certain duct channels, this arrangement can cause separated gas and/or separated air to collect in the relevant subvolume and remain there.

In a further optional embodiment of the invention, in at least one installation position, a subvolume of the air reservoir can be arranged lower than the highest point of the interior cooling surface. This is made possible by a special design of the duct and the air reservoirs, and allows the cooler to be designed more compactly and/or more flexibly. The air reservoir and the interior cooling surface are arranged spaced apart.

In a particularly preferred embodiment of the invention, the air reservoirs may contain compensation elements of plastic that make it possible to modify the total volume enclosed by the cooler. When connecting the cooler to other components of a cooling circuit, undesirable pressure increases may occur within the cooling circuit. For example, when connecting fluid lines filled with liquid, the liquid-carrying volume may be reduced if the liquid/gas quantity remains the same. This can cause the pressure inside the volume to rise. The elastic elements can yield to the pressure and compensate for the pressure increase by increasing the enclosed volume. The elastic compensation elements can be made of foam or designed as gas-filled cushions. In principle, however, any material is conceivable that can yield in the pressure's direction whenever pressure is applied to it.

In addition, a system for cooling a processor is proposed. In addition to the cooler for a processor described above, the system also has a pump and a radiator. The cooler, pump and radiator are connected to each other by fluid lines so that coolant can be pumped through the fluid lines, the cooler duct and the radiator. In the cooler, heat is transferred from the interior cooling surface to the coolant. The coolant that is heated as a result is then directed through the radiator and emits its heat to it. The radiator is usually positioned spaced away from the cooler. The coolant that has cooled down again is then directed back into the cooler to the interior cooling surface, which emits its heat to the coolant again. The cooling circuit described here allows at least one processor emitting its heat to the cooler's outer cooling surface to be cooled. The system may further comprise a fan adapted to cool the radiator, and is preferably arranged on the radiator.

According to yet another aspect, a method to cool a processor is being provided, comprising the following steps. The cooler is aligned in one of its two installation positions. One installation position, for example, may be orientating the cooler, in which the cooler can be attached to a processor. The processor, for example, can be mounted on a circuit board in a PC case. For example, the cooler can also be aligned such that one longitudinal axis of the cooler is horizontal or vertical. The cooler can be designed, for example, so that the exterior cooling surface extends essentially horizontally in a first installation position and/or essentially vertically in a second installation position. However, other embodiments of the process are also conceivable in which the exterior cooling surface is not aligned horizontally and/or vertically in any installation position. In a further step, a coolant is conducted through the cooler's duct. In optional embodiments, the coolant can be conducted to and/or from the cooler via fluid lines. Gas dissolved in the air and/or coolant and/or gas entrained by the coolant can be discharged into the cooler's air reservoir when the liquid is passed through the intended subvolumes, so that the cooler's interior cooling surface is in contact with the coolant. In the process, heat can be transferred to the coolant. It is also conceivable to establish a cooling circuit and to conduct the coolant that has absorbed the heat through a radiator, which absorbs the heat from the coolant. The coolant that has been cooled by the radiator can then be passed through the cooler again.

It goes without saying that the features of the cooler, cooling system and method described above can be combined with each other as long as they do not contradict each other.

Various embodiments of the invention are shown schematically in two figures and are explained below using examples.

Shown are:

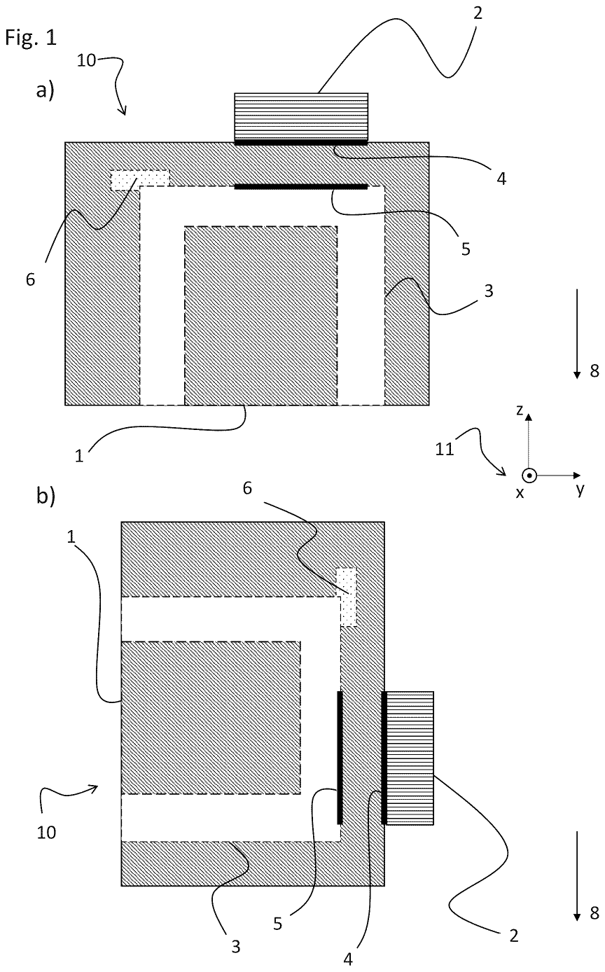

FIG. 1 Sectional views of a first embodiment of cooler for a processor in two installation positions;

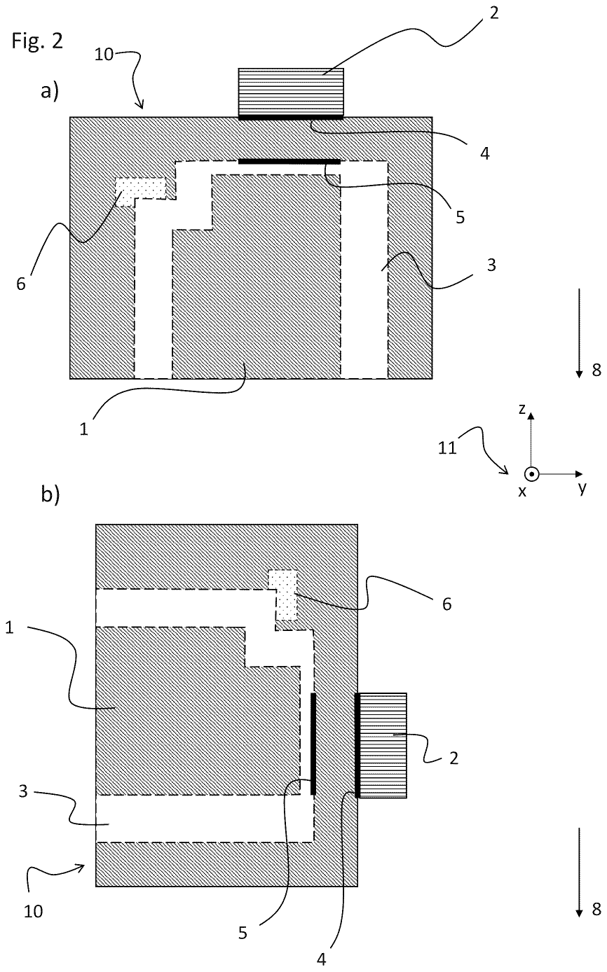

FIG. 2 Sectional views of a second embodiment of a cooler for a processor in two installation positions;

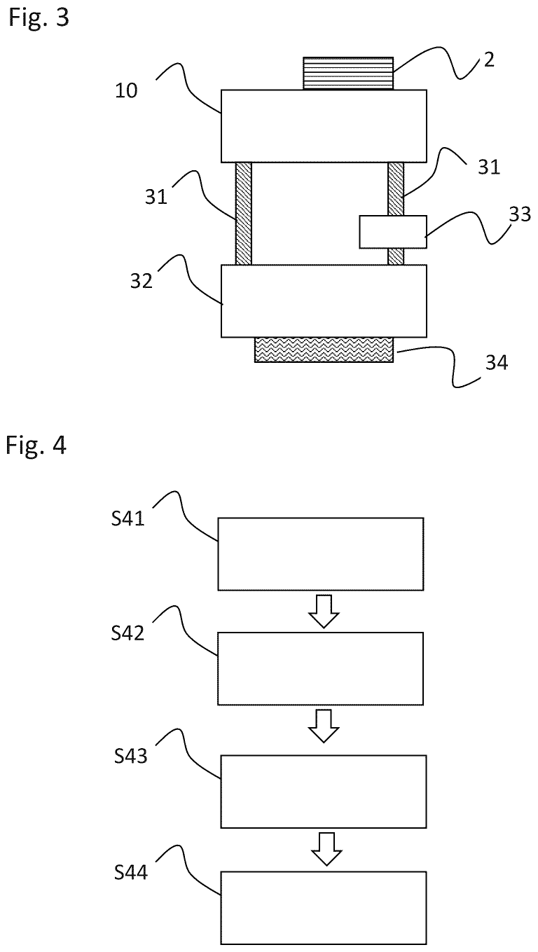

FIG. 3 a schematic representation of a system for cooling a processor; and

FIG. 4 a schematic representation of a process flow for operating a cooler.

FIG. 1 shows sectional views of a first embodiment of a cooler 10 for a processor 2 in two installation positions. In FIG. 1, a direction of gravity 8 points downwards and can be regarded as the negative z-direction of a Cartesian coordinate system 11. FIG. 1a shows a first installation position of the cooler 10 in which the processor 2 is essentially horizontal, FIG. 1b shows the cooler 10 for a processor 2 in a second installation position in which the processor 2 is essentially vertical. FIG. 1b thus shows the cooler 10 for a processor 2 of FIG. 1a, rotated 90° clockwise around the x-axis of the coordinate system 11 shown. The two installation positions shown are to be understood as examples of two installation positions. Installation positions that are not arranged at an angle of 90° to each other are also imaginable. Furthermore, installation positions that are neither vertical nor parallel to the direction of gravity are conceivable.

In the following, the cooler 10 is described in its first installation position, as depicted in FIG. 1a. FIGS. 1a and 1b show a sectional view of a heat sink 1, which is essentially rectangular in profile. The heat sink is not limited to rectangular shapes.

In the first installation position (FIG. 1a), the exterior cooling surface 4 is arranged on a upper side of the heat sink 1. The exterior cooling surface 4 can have optional fastening elements for electronic components, for example for processors 2. The exterior cooling surface 4 itself can optionally be adapted to the surface of an electronic component. Likewise, the exterior cooling surface 4 can be formed from two separate surfaces. Designs in which several exterior cooling surfaces 4 are formed with corresponding interior cooling surfaces 5 are also conceivable. Regardless of this, it may be possible to cool several elements, for example several processors 2 and/or additional electronic components in addition to a processor. In particular, it may be possible that the heat sink 1 is in contact with several elements or areas of a board that produce heat. The cooler 1 can also be designed so that it can absorb heat from at least two electronic components arranged on a printed circuit board, with at least one of these elements being able to come into contact with the at least one exterior cooling surface 4. In some embodiments, the cooler 10 can be designed to absorb the heat from at least two electronic components, which are arranged, for example, on a graphics card. The exterior cooling surface 4 is arranged on a processor 2. A duct 3 runs through the heat sink 1. In the first installation position shown, for example, both an inlet and an outlet for duct 3 are arranged on one underside of the heat sink 1. In this example, duct 3 runs vertically upwards from the inlet, i.e. opposite to the direction of gravity 8, then changes into a horizontal section, and finally runs vertically downwards towards the outlet. The coolant's direction of flow in this embodiment is irrelevant. In this example, there is no preferred direction of flow for the cooling fluid. However, there are certainly embodiments possible in which the direction of flow can be of importance.

An interior cooling surface 5 is formed on the upper side in the horizontal section of the duct 3 as an orthogonal projection of the exterior cooling surface 4. The interior cooling surface 5 is shown as a flat surface in the embodiment depicted. There are also embodiments possible in which the interior cooling surface 5 is convex in the coolant's direction of flow. This means that a connecting line running parallel to the direction of flow between two points of the interior cooling surface 5 runs entirely within the material of the heat sink. Irrespective of this, as regards the interior cooling surface, it is conceivable that the cross-section of duct 3 tapers continuously along the cooling fluid's direction of flow. As regards the interior cooling surface, for example, this can reduce the probability of boundary layer separation, because the cooling fluid's flow velocity in this area is constantly on the rise. Further embodiments, in which the interior cooling surface 5 has ribs that are arranged parallel to the direction of flow, are conceivable. This can, for example, increase the surface area of the interior cooling surface, which facilitates the heat exchange.

The heat sink also has at least one air reservoir 6, which is arranged outside of straight connecting lines or projection lines between the interior cooling surface 5 and the exterior cooling surface 4 and is fluidically connected to the duct 3. The air reservoir 6 in this embodiment is arranged and designed such that in each of the two installation positions, i.e. both in FIG. 1a and FIG. 1b, a subvolume or the total volume of the air reservoir 6 is arranged higher in the direction of gravity than any point of the interior cooling surface 5. If gas and/or air is/are separated from the coolant, it can be collected in the air reservoir 6 so that the interior cooling surface is essentially completely, preferably more than 90%, more than 95% or more than 99%, in contact with the coolant. Embodiments in which the air reservoir 6 has a first air reservoir segment and a second air reservoir segment fluidically connected to one another only via the duct are also conceivable. In this case, the first air reservoir segment can have a first subvolume into which air and/or gas can be separated in the first installation position, and the second air reservoir segment can have a second subvolume into which air and/or gas can be separated in the second installation position.

Furthermore, more than two installation positions in which air can be separated into an air reservoir, for example three, four or more than four installation positions are also conceivable.

FIGS. 2a and 2b also show sectional views of a design of a cooler 10 for a processor in two different installation positions. In a first installation position, as shown in FIG. 2a, an exterior cooling surface 4 extends essentially horizontally, which means that the exterior cooling surface 4 extends essentially orthogonally in the direction of gravity 8. In FIGS. 2a and 2b, the gravity 8 is directed downwards. FIG. 2b shows a sectional view of the cooler 10 for a processor 2 in a second installation position, in which the exterior cooling surface 4 extends essentially in a vertical direction, i.e. parallel to the direction of gravity 8. The cooler 10 in FIG. 2a is described below. Rotating the cooler 10 of FIG. 2a clockwise by 90° around the x-axis of the coordinate system 11, i.e. the axis that is orthogonal to the view level, results in the cooler 10 of FIG. 2b.

In the invention's illustrated embodiment, the heat sink 1 is rectangular in profile. In the example shown in FIG. 2a, a duct 3 runs vertically upwards from an inlet and then merges into a first horizontal section. The first horizontal section is followed by another vertical section that runs upwards and then merges into a second horizontal section. The second horizontal section finally turns into a vertical section that leads to a duct outlet. In this design, the coolant's direction of flow is also irrelevant. In this example, there is no preferred direction of flow for the cooling fluid. However, there are certainly embodiments possible in which the direction of flow can be of importance.

An interior cooling surface 5 is formed in the second horizontal duct section as an orthogonal projection of the exterior cooling surface 4. The duct's cross-section can be smaller in the region of the interior cooling surface 5 than in the two surrounding duct sections, as shown in FIG. 2.

The heat sink has an air reservoir 6, which is connected to the first horizontal duct section. The air reservoir 6 can, for example, be connected to the duct 3 at a point along the duct where there is a risk of a boundary layer separation of the coolant from the duct wall. The dead space created by the boundary layer separation is increased by the air reservoir 6 and serves to absorb and store the separated gas and/or the separated air.

The air reservoir 6 can be designed such that, in the first exemplary installation position shown in FIG. 2a, it is located lower than any point of the interior cooling surface 5. In the second installation position, shown in FIG. 2b, the entire air reservoir 6 is, for example, arranged higher in the direction of the force of gravity 8 than any point on the interior cooling surface 5. Embodiments in which at least one differently sized subvolume of the air reservoir 6 for each installation position is arranged higher than the interior cooling surface 5 are equally possible.

The air reservoir 6 can be designed as a concave bulge in the duct wall, both in FIG. 1 and in FIG. 2.

The heat sink shown 1 can, for example, be made of aluminium or at least partially or predominantly made of it. Regardless of this, the heat sink 1 or parts of the heat sink 1 can be manufactured using an injection moulding, die casting or 3D printing process, for example. In one embodiment of the heat sink 1, it can have restraints to hold the heat sink 1, for example, inside a housing, in particular inside a computer chassis. In an optional design of the heat sink 1, the heat sink 1 can be affixed to sensors whose signals can be used to control and/or to provide control assistance to a cooling circuit.

Optionally, the heat sink 1 can have two or more trays or consist of them. The at least two trays come into contact at the connecting surfaces, are connected to each other at the respective connecting surfaces and, in combination, form the heat sink 1, the duct 3 and the air reservoir(s) 6. The two trays can be shaped such that the duct wall is both part of the first tray and part of the second tray at each point of a certain section along the duct. Optionally, the duct 3 can run at least in sections perpendicular to the trays' connecting surfaces. Regardless of this, the duct 3 can at least partially run parallel to the connecting surfaces and/or at least partially along the connecting surfaces.

In a further optional design, the cooler can have 10 compensation elements, not shown here, with which the total volume enclosed by the heat sink 1 can be changed. The elastic elements can yield when pressure increases and, for example, change their shape or volume. This means that an increase in pressure can be compensated for by an increase in the enclosed volume. The elastic compensation elements can be made of foam or designed as gas-filled cushions. In principle, however, any material is conceivable that can yield in the pressure's direction whenever pressure is applied to it. Independently of this, the compensation elements can be arranged at points in the duct 3 and/or the air reservoir 6.

FIG. 3 shows a schematic representation of a system for cooling a processor 2. The system has a cooler 10 that is fluidically connected to a radiator 32 via fluid lines 31. The cooler can be, for example, one of the coolers 10 from FIG. 1 or 2. The cooler 10 is arranged with its exterior cooling surface 4 on a processor 2. Coolant can be pumped by a pump 33 through fluid lines 31, through a radiator 32 and through the duct 3 of a cooler 10. Heat generated by the processor 2, for example, can be absorbed by the cooler 10 and released to the coolant. The coolant is then pumped through the fluid line 31 to a radiator 32 using pump 33. The radiator 32 enables the coolant to be cooled, for example by releasing the coolant's heat via the radiator 32 into the air surrounding the radiator 32. A system for cooling a processor may also include a fan 34. In FIG. 3, the fan 34 is arranged and/or attached to the radiator 32. The fan 34 can preferably be arranged at least in such a way that the air into which the radiator 32 gives off heat can be moved by the fan 34. The air flow from the fan 34 cools the radiator 32. Instead of the radiator 32, any means are conceivable that can be used to cool the coolant. Optionally or additionally, air cooling that uses fans and/or blowers is also conceivable.

FIG. 4 shows a schematic diagramme of a method for operating a cooler 10, wherein the method comprises the steps S41-S44. The method can be started by aligning the radiator, step S41. The cooler 10 is aligned in one of its two installation positions. The cooler 10 can, for example, be one of the coolers 10 from FIG. 1 or 2. Then, a coolant can be guided through the duct 3 of the cooler 10, see step S42. This can be done, for example, by means of the aforementioned pump 33, which is located in a suitable position. In a further step S43, air and/or gas dissolved in the coolant is/are separated into a subvolume of the air reservoir 6. In addition, heat is transferred from the interior cooling surface 5 of the cooler 10 to the cooling fluid, see step S44. To successfully execute the method, not every step needs to follow another in strict succession. In particular, the flow of the cooling fluid in step S42, the separation of air and/or gas dissolved in the cooling liquid/fluid in step S43 and the transfer of heat to the cooling liquid/fluid in step S44 occur partially simultaneous and/or merge into one another. After steps S42, S43, and S44, the cooler 10 can also be realigned in a new installation position. Further steps may include, for example, switching on the pump 33 and/or using the fan 34 to cool the radiator 32. The method shown in FIG. 4 is thus not limited to steps S41-S44 and may include further steps.

Reference numerals:

| | |
|---|---|
| 1 | heat sink |
| 2 | processor |
| 3 | duct |
| 4 | exterior cooling surface |
| 5 | interior cooling surface |
| 6 | air reservoir |
| 8 | direction of gravity |
| 10 | cooler |
| 11 | coordinate system |
| 31 | fluid line |
| 32 | radiator |
| 33 | pump |
| 34 | fan |
| S41 | aligning the cooler |
| S42 | conveying coolant/cooling fluid |
| S43 | separation of air and/or gas dissolved |
| | in the coolant/cooling fluid |
| S44 | heat dissipation to the |
| | coolant/cooling fluid |

1-14. (canceled)

15. A cooler for a processor for a CPU or a GPU, comprising:
a heat sink with at least one exterior cooling surface for cooling the processor, which is a partial surface of one of the heat sink's outer surfaces,
a duct, which runs through the heat sink, to convey a coolant, and
a first and a second installation position, the cooler being specifically orientated in relation to the force of gravity in each of the two installation positions,
wherein the duct has at least one interior cooling surface which is formed as a projection of the exterior cooling surface onto the nearest interface between the duct and the heat sink,
wherein the heat sink has at least one air reservoir that is connected to the duct,
wherein the air reservoir is arranged outside the projection lines of the interior cooling surface and the exterior cooling surface and is designed such that, in each of the two installation positions, air and/or gas can be separated into at least one subvolume of the air reservoir and the interior cooling surface is in contact with the coolant.

16. The cooler for a processor, according to claim 15, wherein, in each of the two installation positions, at least a subvolume within the air reservoir is arranged higher in the direction of gravity than at least an area of the duct adjacent to the air reservoir.

17. The cooler for a processor, according to claim 15, wherein the cross-section of the duct in the region of the interior cooling surface is smaller than a cross-section of the duct in a directly preceding region in the coolant's direction of flow.

18. The cooler for a processor, according to claim 15, wherein the cooler is orientated in the first installation position such that the at least one exterior cooling surface is perpendicular to the force of gravity and is orientated in the second installation position such that the at least one exterior cooling surface is parallel to the force of gravity.

19. The cooler for a processor, according to claim 15, wherein the air reservoir has a first air reservoir segment and a second air reservoir segment which are connected to one another only via the duct,
wherein the first air reservoir segment has a first subvolume into which air and/or gas is separable in the first installation position, and
the second air reservoir segment has a second subvolume into which air and/or gas is separable in the second installation position.

20. The cooler for a processor, according to claim 15, wherein the exterior cooling surface has an attachment option for the processor.

21. The cooler for a processor, according to claim 15, wherein the cooler comprises two interconnected trays.

22. The cooler for a processor, according to claim 15, wherein the interior cooling surface is flat or has a convex shape.

23. The cooler for a processor, according to claim 15, wherein the at least one air reservoir is designed such that, in each of the two installation positions, at least a subvolume in the air reservoir is arranged higher than any point of the interior-cooling surface in the direction of the force of gravity.

24. The cooler for a processor, according to claim 15, wherein the at least one air reservoir is designed such that, in at least one installation position, the air reservoir is arranged lower than any point of the interior cooling surface in the direction of gravity.

25. The cooler for a processor according to claim 15, with at least one elastic compensation element being arranged within the air reservoir and/or the duct, thus enabling a change in the total volume enclosed by the heat sink.

26. A system for cooling a processor, comprising a cooler for a processor according to claim 15, a pump, and a radiator, which are fluidically connected to one another via fluid lines, wherein a coolant can be pumped through the fluid lines, through the duct of the heat sink, and through the radiator, by way of the at least one pump.

27. The system for cooling a processor according to claim 26, comprising a fan that is designed to cool the radiator and is arranged on the radiator.

28. A method for operating the cooler according to claim 15, whereby
the cooler is aligned in one of its installation positions,
a coolant is conveyed through the duct of the cooler,
air and/or gas dissolved in the coolant is separated into the subvolume of the air reservoir,
and the interior cooling surface is in contact with the cooling fluid such that heat is transferred along the interior cooling surface to the cooling fluid.
